(19) United States
(12) Patent Application Publication
(10) Pub. No.: US 2013/0062101 A1
(43) Pub. Date: Mar. 14, 2013

(54) MULTILAYER WIRING SUBSTRATE, AND MANUFACTURING METHOD FOR MULTILAYER SUBSTRATE

(71) Applicants: Toshinobu Kanai, Osaka (JP); Ryuichi Saito, Mie (JP); Hideki Higashitani, Kyoto (JP)

(72) Inventors: Toshinobu Kanai, Osaka (JP); Ryuichi Saito, Mie (JP); Hideki Higashitani, Kyoto (JP)

(73) Assignee: PANASONIC CORPORATION, Osaka (JP)

(21) Appl. No.: 13/697,774

(22) PCT Filed: Jun. 2, 2011
(86) PCT No.: PCT/JP2011/003106

§ 371 Date: Nov. 13, 2012

(30) Foreign Application Priority Data
Jun. 8, 2010 (JP) 2010-130719

(51) Int. Cl. H05K 1/11; H05K 1/02; H05K 1/03; H05K 3/10

(52) U.S. Cl. 174/251; 29/846; 174/264; 174/258

(57) ABSTRACT

A multilayer wiring board includes inner-layer wiring boards each having wirings on both sides thereof; electrically insulating substrates each having through-holes filled with a conductive paste;

and wirings formed in the outermost layers. The wiring boards and the electrically insulating substrates are stacked alternately in such a manner that the wirings of the wiring boards are embedded in the electrically insulating substrates at both ends of the conductive paste.

### TECHNICAL FIELD

The present invention relates to a multilayer wiring board formed by connecting at least two wiring circuit layers, and a manufacturing method for the multilayer wiring board.

### BACKGROUND ART

As electronic devices are becoming more compact and more densely packed in recent years, circuit boards are strongly demanded to have multilayers in the consumer market as well as in the industrial market.

To achieve such wiring boards, it is essential to develop a method for interconnecting a plurality of wiring circuit layers and also to develop a reliable structure of the wiring circuit layers. There is a suggested method of manufacturing a high density multilayer wiring board by interconnecting a plurality of layers via a conductive paste.

A conventional multilayer wiring board, which is known as a resin multilayer board with any layer IVH structure, is manufactured as shown in FIGS. 11A to 11L.

FIG. 11A shows an electrically insulating substrate 1101.

In FIG. 11B, protective film 1102 is laminated on both sides of electrically insulating substrate 1101.

In FIG. 11C, through-holes 1103 are formed, for example, by laser machining to penetrate electrically insulating substrate 1101 and protective film 1102.

In FIG. 11D, conductive paste 1104 as a conductive material is filled into through-holes 1103. In FIG. 11E, protective film 1102 is removed.

In FIG. 11F, wiring materials 1105 in the form of foil are stacked on both sides of electrically insulating substrate 1101.

In FIG. 11G, wiring materials 1105 are bonded to electrically insulating substrate 1101 through a heat-and-pressure process. The heat-and-pressure process thermally hardens conductive paste 1104, thereby establishing an electrical connection between conductive paste 1104 and wiring materials 1105.

In FIG. 11H, wiring materials 1105 are etched to form circuits, thereby achieving double-sided wiring board 1107, which has wirings 1106.

In FIG. 11I, electrically insulating substrates 1109 and wiring materials 1110 are stacked on both sides of double-sided wiring board 1107. Electrically insulating substrates 1109 include conductive paste 1108 formed by the same procedure shown in FIGS. 11A to 11E.

In FIG. 11J, wiring materials 1110 are bonded to electrically insulating substrates 1109 through a heat-and-pressure process. At the same time, double-sided wiring board 1107 is also bonded to electrically insulating substrates 1109.

The heat-and-pressure process thermally hardens conductive paste 1108 in the same manner as in FIG. 11G, bringing wiring materials 1110 into close contact with double-sided wiring board 1107 via the conductive paste, thereby establishing an electrical connection.

In FIG. 11K, wiring materials 1110 on the outermost layers are etched to form circuits, thereby achieving four-layered wiring board 1112, which has wirings 1111. FIG. 11K shows a four-layered wiring board as an example of the multilayer wiring board; however, the number of layers of the wiring board is not limited to four. For example, as shown in FIG. 11L, ten-layered wiring board 1114 having wirings 1113 can be obtained by repeating the same procedure.

Examples of a conventional technique related to the present invention are described in Patent Literatures 1 and 2 shown in Citation List.

In the above-described procedure to form a multilayer wiring board, the heat-and-pressure process shown in FIG. 11G causes the thermosetting resin contained in electrically insulating substrate 1101 to harden and shrink, thereby generating internal stress, resulting in dimensional shrinkage in the in-plane direction.

When wiring materials 1105 are partially etched in the circuit-forming process shown in FIG. 11H, part of the internal stress is released, increasing the dimension in the in-plane direction. However, some residual stress remains and accumulates with the repetition of the heat-and-pressure process and the circuit-forming process. Thus, increasing the number of layers of the wiring board causes an increase in the positional variation of wirings 1113 of the outermost layers.

Another problem of the conventional manufacturing method for a multilayer wiring board is that the heat-and-pressure process and the wiring-forming process are repeated a required number of times according to the number of wiring layers, which causes an increase in the production period.

### CITATION LIST

### Patent Literature

Patent Literature 1: Japanese Patent Unexamined Publication No. 2000-13023

Patent Literature 2: Japanese Patent Unexamined Publication No. 2004-265890

### SUMMARY OF THE INVENTION

The multilayer wiring board of the present invention includes inner-layer wiring boards each having wirings on both sides thereof; electrically insulating substrates each having through-holes filled with a conductive paste; and wirings formed in the outermost layers. The wiring boards and the electrically insulating substrates are stacked alternately in such a manner that the wirings of the wiring boards are embedded in the electrically insulating substrates at both ends of the conductive paste.

This configuration can prevent dimensional variation in the procedure, which is caused by remaining residual stress, thereby improving the positional precision of the wirings in the outermost layers. As a result, a multilayer wiring board having high interlayer connection reliability can be manufactured with high productivity.

### BRIEF DESCRIPTION OF DRAWINGS

FIG. 1A is a sectional view of a multilayer wiring board according to a first exemplary embodiment of the present invention.

FIG. 1B is a sectional view of the multilayer wiring board according to the first exemplary embodiment.

FIG. 2A is a sectional view showing a step of a manufacturing method of the multilayer wiring board according to the first exemplary embodiment.

FIG. 2B is a sectional view showing a step of the manufacturing method of the multilayer wiring board according to the first exemplary embodiment.

FIG. 2C is a sectional view showing a step of the manufacturing method of the multilayer wiring board according to the first exemplary embodiment.

FIG. 2D is a sectional view showing a step of the manufacturing method of the multilayer wiring board according to the first exemplary embodiment.

FIG. 2E is a sectional view showing a step of the manufacturing method of the multilayer wiring board according to the first exemplary embodiment.

FIG. 2F is a sectional view showing a step of the manufacturing method of the multilayer wiring board according to the first exemplary embodiment.

FIG. 2G is a sectional view showing a step of the manufacturing method of the multilayer wiring board according to the first exemplary embodiment.

FIG. 2H is a sectional view showing a step of the manufacturing method of the multilayer wiring board according to the first exemplary embodiment.

FIG. 2I is a sectional view showing a step of the manufacturing method of the multilayer wiring board according to the first exemplary embodiment.

FIG. 2J is a sectional view showing a step of the manufacturing method of the multilayer wiring board according to the first exemplary embodiment.

FIG. 2K is a sectional view showing a step of the manufacturing method of the multilayer wiring board according to the first exemplary embodiment.

FIG. 3A is a sectional view showing the manufacturing method of the multilayer wiring board according to the first exemplary embodiment.

FIG. 3B shows a register mark used in the multilayer wiring board according to the first exemplary embodiment.

FIG. 3C shows a register mark used in the multilayer wiring board according to the first exemplary embodiment.

FIG. 3D shows a register mark used in the multilayer wiring board according to the first exemplary embodiment.

FIG. 3E shows a register mark used in the multilayer wiring board according to the first exemplary embodiment.

FIG. 3F shows a register mark used in the multilayer wiring board according to the first exemplary embodiment.

FIG. 3G shows a register mark used in the multilayer wiring board according to the first exemplary embodiment.

FIG. 4A is a sectional view showing a manufacturing method of a multilayer wiring board according to the first exemplary embodiment.

FIG. 4B is a sectional view showing the manufacturing method of the multilayer wiring board according to the first exemplary embodiment.

FIG. 4C is a sectional view showing the manufacturing method of the multilayer wiring board according to the first exemplary embodiment.

FIG. 4D is a plan view showing the manufacturing method of the multilayer wiring board according to the first exemplary embodiment.

FIG. 5A is a sectional view showing a manufacturing method of a multilayer wiring board according to the first exemplary embodiment.

FIG. 5B is a sectional view showing the manufacturing method of the multilayer wiring board according to the first exemplary embodiment.

FIG. 5C is a sectional view showing the manufacturing method of the multilayer wiring board according to the first exemplary embodiment.

FIG. 5D is a sectional view showing the manufacturing method of the multilayer wiring board according to the first exemplary embodiment.

FIG. 6A shows how to check the ease of embedding wirings in electrically insulating connection substrates in the first exemplary embodiment.

FIG. 6B shows an example of actual test coupons in the first exemplary embodiment.

FIG. 6C shows an example of a circuit for testing electrical connection in the first exemplary embodiment.

FIG. 7A is a sectional view of a multilayer wiring board according to a second exemplary embodiment of the present invention.

FIG. 7B is a sectional view of the multilayer wiring board according to the second exemplary embodiment.

FIG. 8A is a sectional view showing a step of a manufacturing method of the multilayer wiring board according to the second exemplary embodiment.

FIG. 8B is a sectional view showing a step of the manufacturing method of the multilayer wiring board according to the second exemplary embodiment.

FIG. 8C is a sectional view showing a step of the manufacturing method of the multilayer wiring board according to the second exemplary embodiment.

FIG. 8D is a sectional view showing a step of the manufacturing method of the multilayer wiring board according to the second exemplary embodiment.

FIG. 8E is a sectional view showing a step of the manufacturing method of the multilayer wiring board according to the second exemplary embodiment.

FIG. 8F is a sectional view showing a step of the manufacturing method of the multilayer wiring board according to the second exemplary embodiment.

FIG. 8G is a sectional view showing a step of the manufacturing method of the multilayer wiring board according to the second exemplary embodiment.

FIG. 8H is a sectional view showing a step of the manufacturing method of the multilayer wiring board according to the second exemplary embodiment.

FIG. 8I is a sectional view showing a step of the manufacturing method of the multilayer wiring board according to the second exemplary embodiment.

FIG. 8J is a sectional view showing a step of the manufacturing method of the multilayer wiring board according to the second exemplary embodiment.

FIG. 8K is a sectional view showing a step of the manufacturing method of the multilayer wiring board according to the second exemplary embodiment.

FIG. 8L is a sectional view showing a step of the manufacturing method of the multilayer wiring board according to the second exemplary embodiment.

FIG. 8M is a sectional view showing a step of the manufacturing method of the multilayer wiring board according to the second exemplary embodiment.

FIG. 8N is a sectional view showing a step of the manufacturing method of the multilayer wiring board according to the second exemplary embodiment.

FIG. 9A is a sectional view of a multilayer wiring board according to a third exemplary embodiment of the present invention.

FIG. 9B is a sectional view of the multilayer wiring board according to the third exemplary embodiment.

FIG. 10A is a sectional view showing a step of a manufacturing method of the multilayer wiring board according to the third exemplary embodiment.

FIG. 10B is a sectional view showing a step of the manufacturing method of the multilayer wiring board according to the third exemplary embodiment.

FIG. 10C is a sectional view showing a step of the manufacturing method of the multilayer wiring board according to the third exemplary embodiment.

FIG. 10D is a sectional view showing a step of the manufacturing method of the multilayer wiring board according to the third exemplary embodiment.

FIG. 10E is a sectional view showing a step of the manufacturing method of the multilayer wiring board according to the third exemplary embodiment.

FIG. 10F is a sectional view showing a step of the manufacturing method of the multilayer wiring board according to the third exemplary embodiment.

FIG. 10G is a sectional view showing a step of the manufacturing method of the multilayer wiring board according to the third exemplary embodiment.

FIG. 10H is a sectional view showing a step of the manufacturing method of the multilayer wiring board according to the third exemplary embodiment.

FIG. 10I is a sectional view showing a step of the manufacturing method of the multilayer wiring board according to the third exemplary embodiment.

FIG. 10J is a sectional view showing a step of the manufacturing method of the multilayer wiring board according to the third exemplary embodiment.

FIG. 10K is a sectional view showing a step of the manufacturing method of the multilayer wiring board according to the third exemplary embodiment.

FIG. 10L is a sectional view showing a step of the manufacturing method of the multilayer wiring board according to the third exemplary embodiment.

FIG. 10M is a sectional view showing a step of the manufacturing method of the multilayer wiring board according to the third exemplary embodiment.

FIG. 10N is a sectional view showing a step of the manufacturing method of the multilayer wiring board according to the third exemplary embodiment.

FIG. 10O is a sectional view showing a step of the manufacturing method of the multilayer wiring board according to the third exemplary embodiment.

FIG. 10P is a sectional view showing a step of the manufacturing method of the multilayer wiring board according to the third exemplary embodiment.

FIG. 11A is a sectional view showing a step of a conventional manufacturing method of a multilayer wiring board.

FIG. 11B is a sectional view showing a step of the conventional manufacturing method of the multilayer wiring board.

FIG. 11C is a sectional view showing a step of the conventional manufacturing method of the multilayer wiring board.

FIG. 11D is a sectional view showing a step of the conventional manufacturing method of the multilayer wiring board.

FIG. 11E is a sectional view showing a step of the conventional manufacturing method of the multilayer wiring board.

FIG. 11F is a sectional view showing a step of the conventional manufacturing method of the multilayer wiring board.

FIG. 11G is a sectional view showing a step of the conventional manufacturing method of the multilayer wiring board.

FIG. 11H is a sectional view showing a step of the conventional manufacturing method of the multilayer wiring board.

FIG. 11I is a sectional view showing a step of the conventional manufacturing method of the multilayer wiring board.

FIG. 11J is a sectional view showing a step of the conventional manufacturing method of the multilayer wiring board.

FIG. 11K is a sectional view showing a step of the conventional manufacturing method of the multilayer wiring board.

FIG. 11L is a sectional view showing a step of the conventional manufacturing method of the multilayer wiring board.

### DESCRIPTION OF EMBODIMENTS

Embodiments of the present invention are described with reference drawings.

### First Exemplary Embodiment

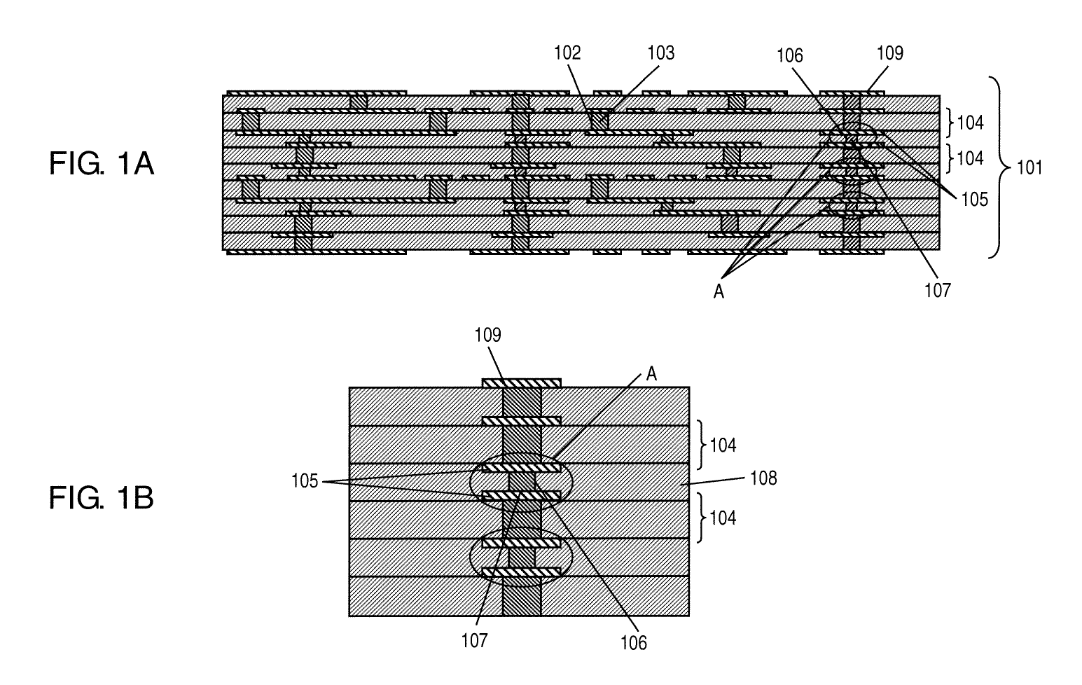

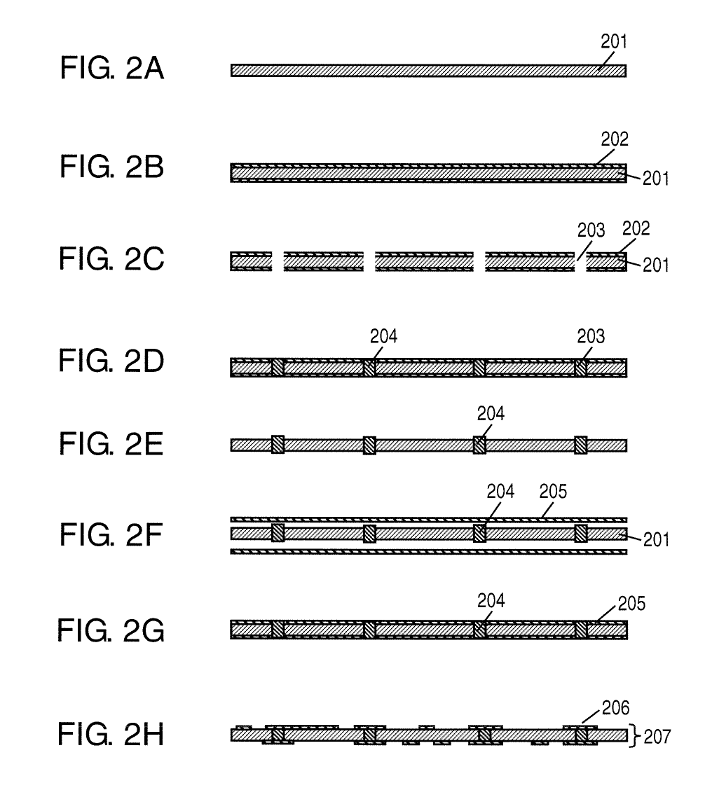

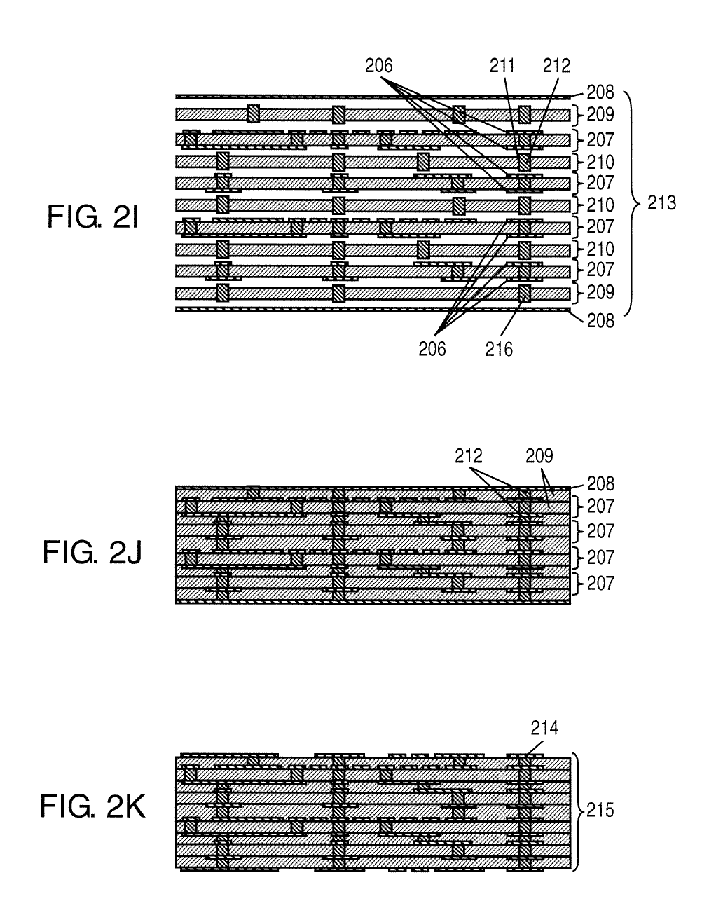

FIGS. 1A, 1B, 2A-2K show a configuration and a manufacturing method of a multilayer wiring board according to a first exemplary embodiment of the present invention.

FIG. 1A shows ten-layered wiring board 101 as an example of the multilayer wiring board according to the present invention.

Ten-layered wiring board 101 shown in FIG. 1A has through-holes 102 filled with conductive paste 103, thereby establishing an electrical connection between wirings in the same manner as in the conventional example. Ten-layered wiring board 101 includes connection regions “A” where double-sided wiring boards 104 having wirings 105 are disposed at both ends of conductive paste 107 filled in through-holes 106 so as to compress conductive paste 107 more effectively.

The connection regions “A” shown in FIG. 1A are now described in detail with reference to FIG. 1B showing an enlarged view of connection regions “A”.

Wirings 105 disposed on both sides of conductive paste 107 in the connection regions “A” are previously formed on the front and rear sides of adjacent double-sided wiring boards 104 in such a manner as to project from double-sided wiring boards 104. Wirings 105 are embedded in electrically insulating substrates 108 at both ends of conductive paste 107 in such a manner as to strongly compress conductive paste 107.

As a result, conductive paste 107 can provide a more stable electrical connection, and through-holes 106 can be made smaller in diameter.

Double-sided wiring boards 104, which are formed through a one-time heat-and-pressure process and a one-time circuit-forming process, have comparatively small variations in positioning precision of wirings 105 which are caused by variations in residual stress.

As a result, double-sided wiring boards 104 can be highly aligned with conductive paste 107.

Ten-layered wiring board 101 is formed through a two-time heat-and-pressure process and a two-time circuit-forming process. This allows wirings 109, which are formed in the outermost layers shown in FIG. 1A to have low variations in residual stress, thereby having higher positioning precision than in the conventional example.

Thus, in the multilayer wiring board of the present invention, the positioning precision of wirings 109 formed in the outermost layers can be close to the design value because of their low positional variation and high positioning precision.

This results in reducing the tolerance of misalignment between the solder mask and the wirings.

In the multilayer wiring board of the present invention, the excellent positioning precision of wirings 109 facilitates the positioning between wiring 109 and IC chips via solder bumps in bare chip mounting or ACF mounting.

A manufacturing method for the multilayer wiring board according to the first exemplary embodiment is now described with reference to FIGS. 2A to 2K.

FIG. 2A shows electrically insulating substrate 201. In FIG. 2B, protective film 202 is laminated on both sides of electrically insulating substrate 201.

Electrically insulating substrate 201 is a composite of fiber and resin. This composite can be formed, for example, by impregnating glass fiber or organic fiber with epoxy resin, polyimide resin, BT resin, PPE resin, or PPO resin; impregnating porous film such as polyimide, aramid, PTFE, or LCP with epoxy resin, polyimide resin, BT resin, PPE resin, PPO resin; or by applying adhesive to both sides of polyimide, aramid, or LCP film.

The resin used in the composite is preferably a thermosetting-type resin because it has excellent formability during the lamination of the multilayer wiring board.

Electrically insulating substrate 201 is more preferably a porous compressible substrate. In brief, electrically insulating substrate 201 is preferably made of a material that can be compressed when pressed in the thickness direction. The degree of compression can be adjusted by controlling holes formed in electrically insulating substrate 201.

To achieve such characteristics, electrically insulating substrate 201 can be formed by impregnating a woven or nonwoven fabric (including paper) with resin. The holes can be formed at the same time as the impregnation.

Using nonwoven paper mainly made of aramid resin as the paper, and also using thermosetting resin mainly made of epoxy as the resin can form the holes in electrically insulating substrate 201 uniformly and efficiently, thereby achieving a highly compressible insulating substrate.

The thickness of electrically insulating substrate 201 can be set as desired by adjusting the thickness of materials such as glass fiber or organic fiber to, for example, 20 to 200 microns.

For simple and productive manufacturing method, protective film 202 is mainly made of PET or PEN, and is laminated on both sides of electrically insulating substrate 201.

In FIG. 2C, through-holes 203 are formed, for example, by laser machining to penetrate electrically insulating substrate 201 and protective film 202. Through-holes 203, which can be formed by punching, drilling, or laser machining, can be formed by carbon dioxide laser or YAG laser to make them smaller in diameter in a shorter time, thereby providing high production efficiency.

In the case of carbon dioxide laser, through-holes can have a diameter of 100 microns in electrically insulating substrate 201 having a thickness of 80 microns. On the other hand, in the case of a third harmonic of YAG laser, through-holes can have a diameter of 30 microns in electrically insulating substrate having a thickness of 30 microns.

In FIG. 2D, conductive paste 204 as a conductive material is filled into through-holes 203. Conductive paste 204 contains conductive metal particles such as copper or silver, and resin components. The conductive particles are preferably substantially spherical so that the paste viscosity can remain low even if conductive paste 204 has a high proportion of conductive particles.

The conductive metal particles of conductive paste 204 may be of a type that can be melted and alloyed in a heat-and-pressure process described later, thereby having higher electrical connection reliability.

Such conductive particles can be the following: a low-melting-point metal such as tin; a low-melting-point metal to which silver, bismuth, or other metals has been added; an alloy of tin and silver, bismuth, or other metals; or copper having a surface coated with a low-melting-point metal.

In FIG. 2E, protective film 202 is removed.

The presence of protective film 202 increases the amount of conductive paste 204 to be filled. More specifically, conductive paste 204 projects from the surface of electrically insulating substrate 201 by a height corresponding to the thickness of protective film 202. The thickness of protective film 202 is preferably set to be 5% to 25% of the diameter of through-holes 203 so as to reduce the amount of conductive paste 204 to be lost when protective film 202 is removed.

In FIG. 2F, wiring materials 205 in the form of foil are stacked on both sides of electrically insulating substrate 201.

In FIG. 2G, wiring materials 205 are bonded to electrically insulating substrate 201 through a heat-and-pressure process. Conductive paste 204 filled in through-holes 203 contain a lot of resin between the conductive particles, and has not yet established a sufficient electrical connection.

The heat-and-pressure process, however, applies compression to conductive paste 204, bringing the conductive particles into close contact with each other, thereby establishing an electrical connection, and also bringing wiring materials 205 into close contact with conductive paste 204, thereby establishing an electrical connection via conductive paste 204.

On the other hand, in the case of using the conductive paste containing conductive metal particles that can be melted and alloyed in the heat-and-pressure process, the heat-and-pressure process allows the formation of alloy layers between the conductive metal particles and between the wiring materials and the conductive particles, thereby establishing a more reliable electrical connection.

Wiring materials 205 used in this embodiment are a 9-micron thick electrolytic copper foil, but the thickness is not limited to this. To achieve a thinner multilayer wiring board, it is possible to use a 5-micron thick electrolytic copper foil with carrier foil or a 5-micron thick rolled copper foil.

Using a double treated foil made by electroplating both surfaces of a copper foil provides excellent adhesion because the surfaces can be rough like octopus pots.

Wiring materials 205 may be made of copper foil that has a roughened surface on the side facing electrically insulating substrate 201. The copper foil is then subjected to etching or other chemical treatments so as to have small asperities on its surface after a heat-and-pressure process, which will be described later. This method enables the copper foil applied to the electrically insulating substrate to be etched uniformly so as to provide fine wirings 206.

In FIG. 2H, wiring materials 205 are etched to form circuits, thereby achieving, as an inner layer, double-sided wiring board 207 having wirings 206. Double-sided wiring board 207, which is formed through a one-time heat-and-pressure process and a one-time circuit-forming process, has comparatively small variations in positioning precision of the wirings, which are caused by residual stress. The circuits can be formed by photography using a pattern film, but are preferably laser drawn, for example, by using a semiconductor laser so as to have higher wiring precision.

FIG. 2I shows laminated plate 213 formed by stacking wiring materials 208, electrically insulating connection substrates 209 and 210, and double-sided wiring boards 207. Electrically insulating connection substrates 209 and 210 are formed in the same procedure as shown in FIGS. 2A to 2E by forming through-holes 211 in electrically insulating substrate 201 and filling conductive paste 212 into through-holes 211. The position and dimension of wirings 206 of double-sided wiring boards 207 having small wiring variations are previously measured, and the measurement results are used to correct the position data of through-holes 211 of electrically insulating connection substrates 209 and 210. As a result, through-holes 211 can be highly aligned with wirings 206.

In this case, electrically insulating connection substrates 209 and 210 can be classified according to the measurement results of the position and dimension of the wirings. Of all electrically insulating connection substrates 209 and 210, those having wirings 206 and through-holes 211 aligned with each other can be selected for use. This provides a multilayer wiring board where wirings 206 are highly aligned with through-holes 211 filled with conductive paste 212.

Wirings 206 projecting from double-sided wiring boards 207 can effectively compress conductive paste 212 of electrically insulating connection substrates 210. As a result, conductive paste 212 can provide a more stable electrical connection, and through-holes 211 can be made smaller in diameter.

To achieve stable electrical connection, wirings 206 on at least one side of each double-sided wiring board 207 can be made thicker.

Alternatively, the same effect can be obtained by making protective film 202 shown in FIG. 2B thicker when applied to the electrically insulating connection substrates so that conductive paste 204 can project higher.

To achieve more stable electrical connection, the conductive paste more preferably contains conductive particles that can be melted in the heat-and-pressure process. Since electrically insulating connection substrates 210 need to be embedded with larger wirings than electrically insulating connection substrates 209, it is preferable to increase the resin content of their materials or the fluidity of the resin at high temperatures. An increase in the content or fluidity of the resin decreases the connection when the conductive paste is compressed. According to the structure of the present invention, however, the electrical connection of conductive paste 212 can be secured by embedding wirings at both ends of through-holes 211 and applying high compressive pressure.

There are cases of increasing the content or fluidity of the resin in the electrically insulating connection substrates or the thickness of the electrically insulating connection substrates in order to improve the ease of embedding wirings. In such cases, the diameter of through-holes 211 can be made larger than the diameter of the through-holes formed in double-sided wiring boards 207 so that the through-hole vias can provide high connection reliability.

The diameter of the through-holes formed in the electrically insulating connection substrates can be larger than the diameter of the through-holes formed in the double-sided wiring board in the other cases, too.

It is not necessary for all layers to have wirings of a uniform thickness; it is preferable to determine the thickness of the wirings according to the function of each layer. For example, to create fine wirings, the thickness can be thin, and to reinforce the ground, the thickness can be thick.

Also, it is possible to change the thickness of the wirings according to the design pattern or the fluidity of the resin, thereby improving the stability of molding the resin in the heating and pressing process.

To obtain a high yield of finished products, it is further preferable that double-sided wiring boards 207 that were found to have short-circuit or breakage be replaced by other double-sided wiring boards 207 having no such problems.

In FIG. 2J, wiring materials 208 are bonded to electrically insulating connection substrates 209 through a heat-and-pressure process.

At the same time, double-sided wiring boards 207 are also bonded to electrically insulating connection substrates 209. The heat-and-pressure process thermally hardens conductive pastes 212 and 216 in the same manner as in FIG. 2G, bringing double-sided wiring boards 207 into close contact with each other, and also bringing double-sided wiring boards 207 into close contact with wiring materials 208 via conductive pastes 212 and 216, thereby establishing an electrical connection.

In FIG. 2K, wiring materials 208 on the outermost layers are etched to form circuits, thereby achieving ten-layered wiring board 215, which has wirings 214.

The circuits can be formed by photography using a pattern film, but are preferably laser drawn, for example, by using a semiconductor laser so as to have higher wiring precision. Ten-layered wiring board 215 is formed through a two-time heat-and-pressure process and a two-time circuit-forming process as described above. This allows wiring 214 to have low position variations, which are caused by variations in residual stress, thereby having higher positioning precision than wiring 214 used in the conventional example.

The first exemplary embodiment has described the ten-layered wiring board as an example of a multilayer wiring board; however, the number of layers of the wiring board is not limited to ten, and can alternatively be, for example, 6, 8, 10, or 12 by changing the number of components to be alternately stacked in FIG. 21.

The manufacturing method according to the first exemplary embodiment allows a wiring board to be manufactured through a two-time heat-and-pressure process and a two-time circuit-forming process regardless of the number of layers of the wiring board. This has an advantage of being highly productive in forming a multilayer wiring board having a large number of layers.

In the stacking process shown in FIG. 2I, the layers are preferably aligned by providing a register mark to each layer and then temporarily fixing the layers.

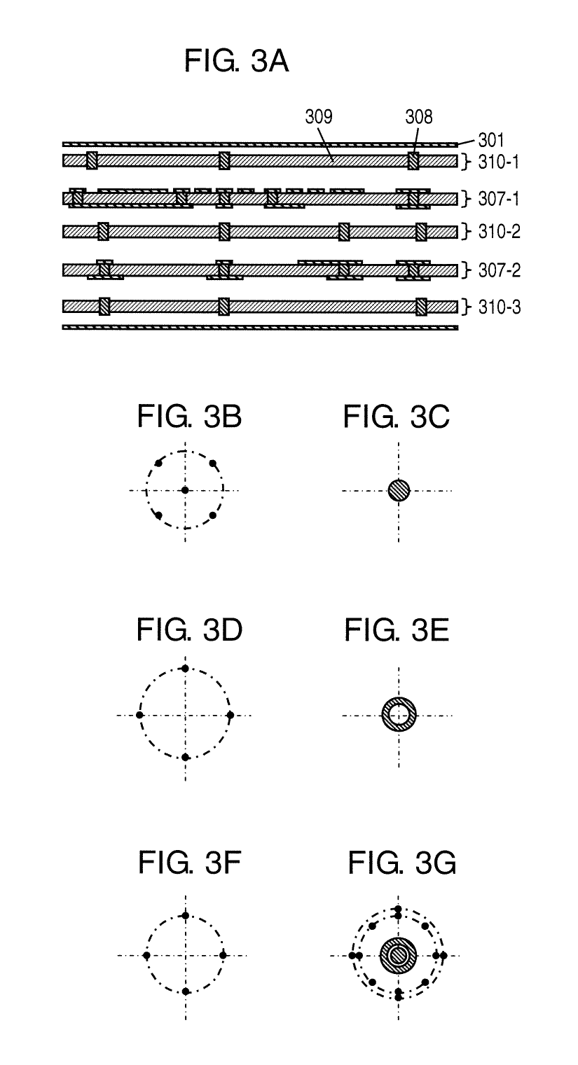

The register marks used for stacking are now described by taking the stacking process for the six-layered wiring board shown in FIG. 3A as an example. The register marks preferably enable misalignment of the stacked layers to be recognized and detected from a narrow field of vision during stacking.

As shown in FIG. 3B, a concentric circular mark including a plurality of through-hole vias is used as a register mark for electrically insulating connection substrate 310-1. The center position of the register mark including the plurality of through-hole vias can be determined with high precision by image recognition or other methods. Such high precision is impossible to achieve in the case of using a single through-hole via because of positional variations.

Furthermore, changing the arrangement of the concentric circular through-hole vias or the diameter of the concentric circles allows the recognition of the relative positional relationship of through-hole vias formed in electrically insulating connection substrates 310-1, 310-2, and 310-3. The center positions of the register marks shown in FIGS. 3B, 3D, and 3F can be calculated by image recognition or other methods and be aligned with each other in a stacking process. As a result, the plurality of electrically insulating connection substrates can be stacked with high precision.

On the other hand, register marks differing in pattern and size can be disposed on double-sided wiring boards 307-1 and 307-2 as shown in FIGS. 3C and 3E, respectively. This allows the center positions of the register marks shown in FIGS. 3C and 3E to be determined by image recognition or other methods and to be aligned with each other, thereby recognizing the relative positional relationship of the patterns formed in the plurality of double-sided wiring boards. The center positions of the register marks shown in FIGS. 3C and 3E can be aligned with each other in a stacking process so that the plurality of double-sided wiring boards can be stacked with high precision.

Furthermore, as shown in FIG. 3G, the center positions of the register marks shown in FIGS. 3B, 3D, and 3F for electrically insulating connection substrates 310-1, 310-2, and 310-3 and the center positions of the register marks shown in FIGS. 3C and 3E for double-sided wiring boards 307-1 and 307-2 can be determined by image recognition during stacking, and be aligned with each other. This results in a multilayer wiring board with high precision of stacking. In a test conducted after all the layers are stacked, the register mark of FIG. 3G can be recognized by an X-ray camera or other method, enabling misalignment of the stacked layers to be detected from a narrow field of vision, based on the relative positional relationship between the register marks of all the layers. Using a different register mark for each layer can prevent making a mistake in the order of stacking.

The through-hole vias and patterns shown as the register marks have circular shapes, but it is understood that they are not limited to circular shapes to provide the same effect. It is also understood that the register marks for a double-sided wiring board can be provided on both sides. In this case, the wirings of the double-sided wiring board and the through-hole vias formed in an electrically insulating connection substrate can be aligned not only on the upper surface but also on the bottom surface of the double-sided wiring board.

As an approach to recognizing the register marks used in stacking the multilayer wiring board shown in FIG. 3A, it is possible to use a camera, reflected light, transmitted light, or X-ray according to circumstances. It is possible to perform alignment between a register mark formed on the upper surface of a double-sided wiring board and a register mark formed by through-hole vias on an electrically insulating connection substrate. Alignment can also be performed between the register mark for an electrically insulating connection substrate and the register marks formed on the upper and lower surfaces of a double-sided wiring board, thereby providing a multilayer wiring board with high precision of stacking.

The register mark formed on the bottom surface of a double-sided wiring board can be recognized by placing cameras not only in an upper part but also in a lower part of a laminated plate. The through-hole vias formed in an electrically insulating connection substrate and the register mark formed in the wirings on the bottom surface of a double-sided wiring board can be recognized through a prism of a camera placed in an upper part of the laminated plate.

As another approach, through-holes can be formed in a double-sided wiring board with reference to the register mark on its bottom surface, and the through-holes can be aligned with the register mark formed on an electrically insulating connection substrate, thereby aligning the wirings on the bottom surface of the double-sided wiring board and the through-hole vias in the electrically insulating connection substrate. Any of these approaches can improve alignment between the wirings on a double-sided wiring board and the through-hole vias in an electrically insulating connection substrate, thereby providing a multilayer wiring board with high precision of stacking.

A method for the temporary fixation of the stacked layers is now described.

Double-sided wiring boards, electrically insulating connection substrates, and wiring materials are arranged and temporarily fixed so as to prevent misalignment during handling before a heat-and-pressure process.

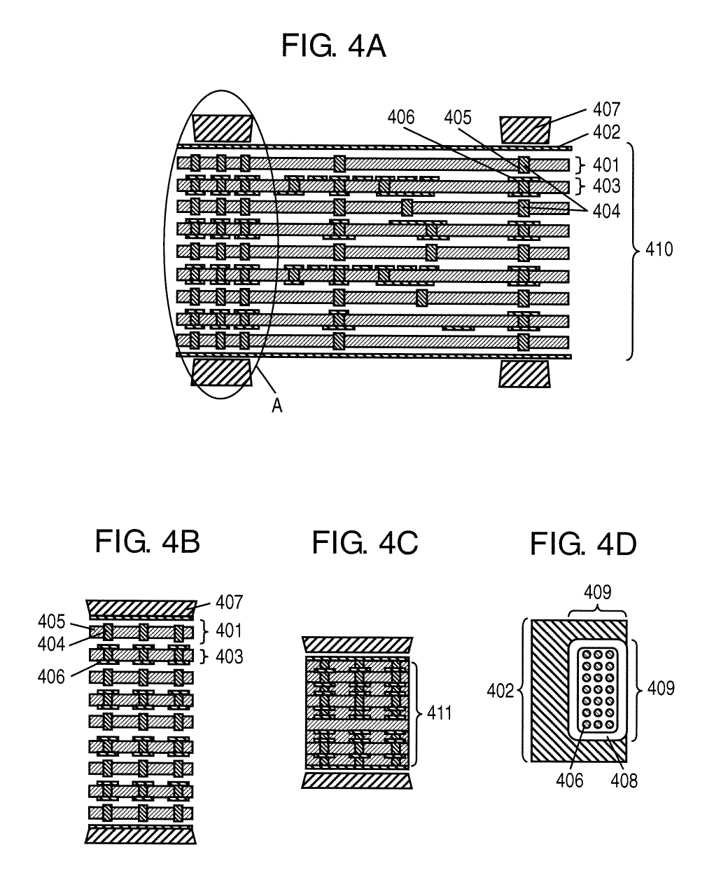

One approach to temporary fixation is to partially weld electrically insulating connection substrates 401. More specifically, as shown in FIG. 4A, after stacking is completed as shown in FIG. 2I, electrically insulating connection substrates 401 are partially welded by applying heat and pressure to a part of laminated plate 410 using heated heat tools 407. As a result, electrically insulating connection substrates 401 are positioned and fixed with respect to wiring materials 402 and double-sided wiring boards 403. Wiring materials 402 and double-sided wiring boards 403 are disposed respectively on and under electrically insulating connection substrate 401.

However, as the number of layers of the wiring board increases, the required heat capacity increases, preventing the electrically insulating connection substrates from being fully bonded to the double-sided wiring boards that are away from the heat tools.

This problem can be solved by providing welded areas 409 where the wiring materials on the outermost layers have been selectively removed as shown in FIG. 4D. This facilitates heat transfer from heat tools 407 to electrically insulating connection substrates 401 and double-sided wiring boards 403.

To facilitate the heat transfer from heat tools 407 to electrically insulating connection substrates 401 and double-sided wiring boards 403, as shown in FIG. 4B, each welded area 409 has through-holes 405 filled with conductive paste 404, and wirings 406 connected to through-holes 405 in electrically insulating connection substrate 401 and double-sided wiring board 403 directly underneath heat tool 407.

The same effect can be obtained also in the case where welded areas 409 include only conductive paste 404 and do not have wirings 406. FIG. 4C shows welded area cross section 411 after welded areas 409 are welded.

As shown in FIG. 4D, it is preferable to provide no-wiring areas 408 in the vicinity of the welded regions in order to prevent heat loss to wiring materials 402. It is also preferable that welded areas 409 are equal to or larger than heat tools 407. This allows the heat of heat tools 407 to be efficiently transferred to laminated plate 410.

Heat tools 407 are preferably capable of changing conditions such as temperature and pressure according to the thickness of an object to be welded.

In the above-described method for temporary fixation, each layer is stacked first, and then all the layers are welded together. Alternatively, each electrically insulating connection substrate 401 and each double-sided wiring board 403 can be welded starting from the bottom using heat tools 407. This requires a smaller heat capacity than in the case of welding the laminated plate in one operation, thereby allowing precise positioning and temporary fixation.

As described above, providing welded areas 409 facilitates heat transfer, thereby achieving a multilayer wiring board with higher precision of stacking.

In the case where double-sided wiring boards 403 are formed into a four-layered wiring board, the welded regions can be counterbored to be partially made thin so as to increase thermal conductivity, thereby providing the same effect.

In the above-described example, welded areas 409 are provided in laminated plate 410, and are heated and pressed for temporary fixation. Temporary fixation can alternatively be achieved by heating and pressing the entire surfaces of electrically insulating connection substrates 401 or the entire surfaces of double-sided wiring boards 403. This increases the bonding of electrically insulating connection substrates 401 or double-sided wiring boards 403 during temporary fixation after the stacking, thereby achieving a multilayer wiring board with high precision.

In the above description, the temporary fixation is achieved by applying heat and pressure; however, it is understood that the layers can be bonded by using an adhesive.

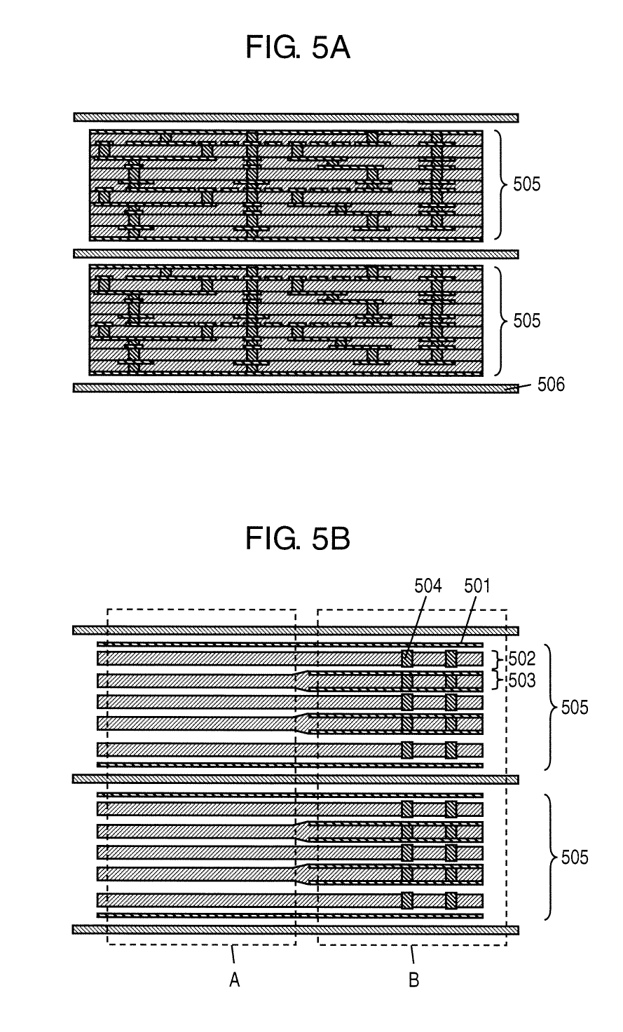

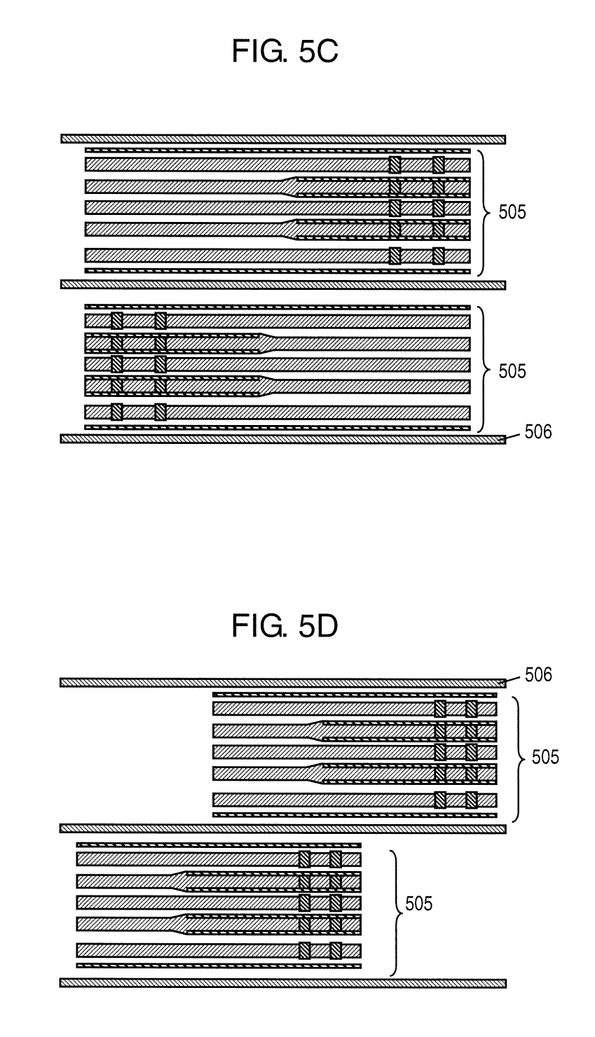

In the heat-and-pressure process shown in FIG. 2J, a plurality of laminated plates can be stacked with SUS plates 506 disposed therebetween as shown in FIG. 5A, and be heated and pressed, thereby increasing productivity. In this example, two laminated plates are stacked to perform a heat-and-pressure process; however, it is understood that three or more laminated plates can be stacked.

Stacking a plurality of laminated plates to perform a heat-and-pressure process unfortunately makes it harder to press all the laminated plates uniformly.

For example, as shown in FIG. 5B, there is an apparent partial difference in thickness between a region “B” where the laminated plates have wirings and through-hole vias, and a region “A” where the laminated plates do not have wirings or through-hole vias. In brief, the region “B” is thicker than the region “A”. A pressure applied in this state, however, does not act on the region “A”. Note that in FIG. 5B, laminated plates 505 are illustrated separately as before being stacked.

In the case where the densities in wirings and in through-hole vias are greatly different from part to part in laminated plates 505, laminated plates are stacked in alternate directions as shown in FIG. 5C, or in a displaced manner as shown in FIG. 5D. This allows pressure to be applied uniformly in the heat-and-pressure process.

Furthermore, it is preferable for a laminated plate as a product to have no imbalance in the densities in wirings and in through-hole vias. In the case where there is such imbalance, wirings and through-hole vias are preferably disposed in the portions of a board that are to be discarded or outside the product portion.

The following is a description of test coupons for testing the ease of embedding the resin in the electrically insulating connection substrates and the electrical connection of the conductive paste after wirings are formed in the outermost layers of a multilayer wiring board completed by one batch lamination process.

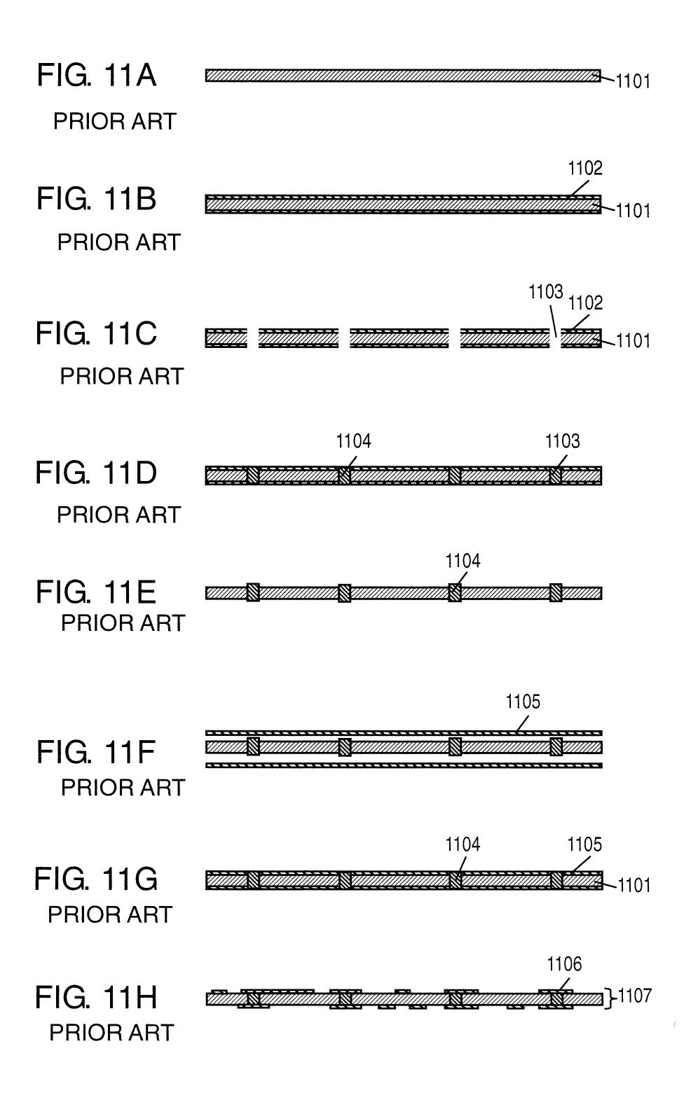

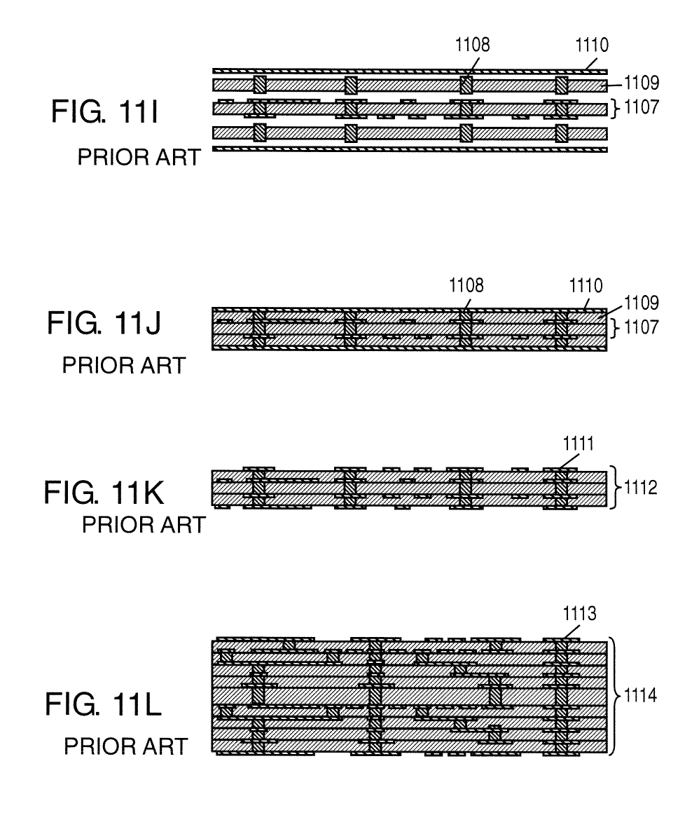

In the multilayer wiring board manufactured by the procedure shown in FIGS. 2A to 2K, heat and pressure are applied in one batch unlike the conventional method shown in FIGS. 11A to 11L where each layer is individually heated and pressed. Hence, even if the board has voids due to the lack of embedded resin, it is very hard to recognize it by appearance. This is why it is preferable to provide test coupons.

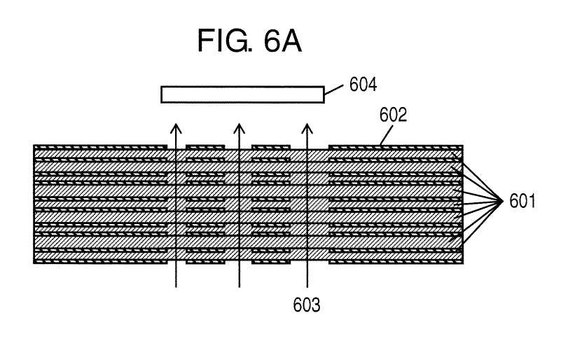

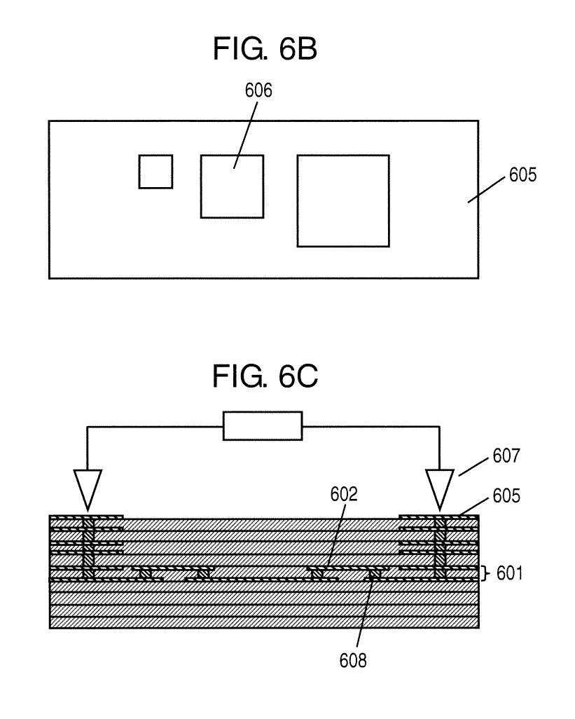

FIG. 6A shows how to check the ease of embedding wirings in the electrically insulating connection substrates. This is evaluated by applying light 603 to test coupons disposed in substrates having a given work size, and using sensor 604 to sense the difference of light transmittance between the test coupons.

FIG. 6B shows an example of the test coupons. In FIG. 6B, a plurality of different sized no-wiring patterns 606 containing no patterns are disposed on all layers, and are subjected to heat and pressure to evaluate the ease of embedding wirings by the above-described method. This evaluation can determine how much area of each electrically insulating connection substrate can be used for embedding wirings.

Furthermore, the area of no-wiring patterns 606 containing no patterns can be made equal to the no-wiring area in the products to determine whether the products have sufficient ease of embedding wirings or not.

It is preferable to dispose the test coupons not only in accordance with the work size but also in accordance with the product sheet size because this allows checking the ease of embedding wirings for every product, thereby providing high detection sensitivity.

To determine whether a completed multilayer wiring board has sufficient ease of embedding resin, the multilayer wiring board can be subjected to heat history such as reflow, thereby classifying the ease of embedding resin into different levels.

A circuit for testing the electrical connection of electrically insulating connection substrates 601 is now described.

FIG. 6C shows an example of a circuit for the testing. In this circuit, electrically insulating connection substrates 601 have through-hole vias 606, which are connected in series with wirings 602, which are formed in the upper and lower layers of electrically insulating connection substrates 601. The electric resistance can be checked from the outermost layer.

Providing the test coupons allows the measurement of the resistance from the outermost layer, thereby facilitating the evaluation of the through-hole via connection of electrically insulating connection substrates 601.

This method is not limited to specific layers, and is applicable to any layer including electrically insulating connection substrate 601.

The circuit shown in FIG. 6C is one example, and any other circuit can be used as long as the circuit includes electrically insulating connection substrate 601 having through-hole vias connected in series.

### Second Exemplary Embodiment

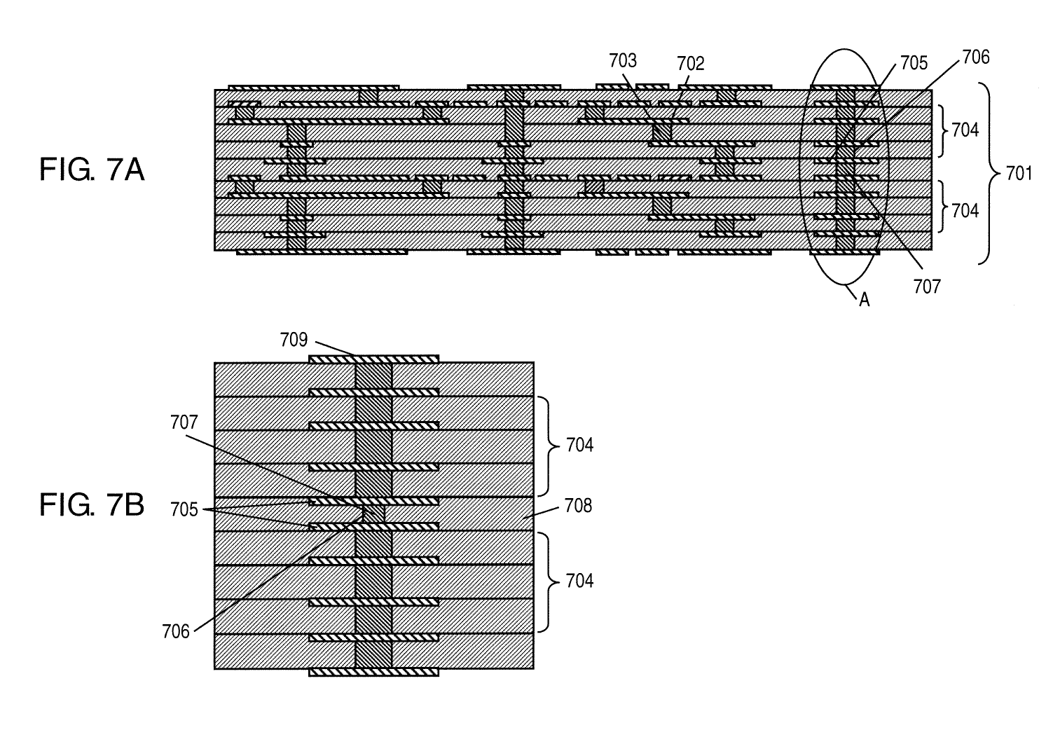

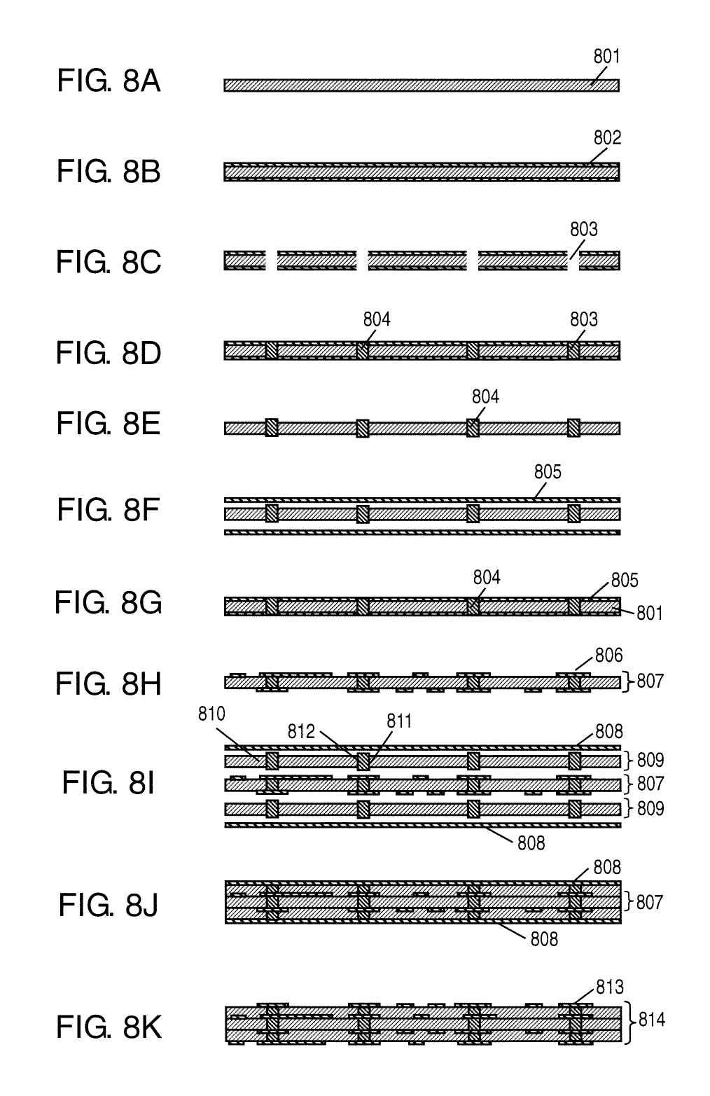

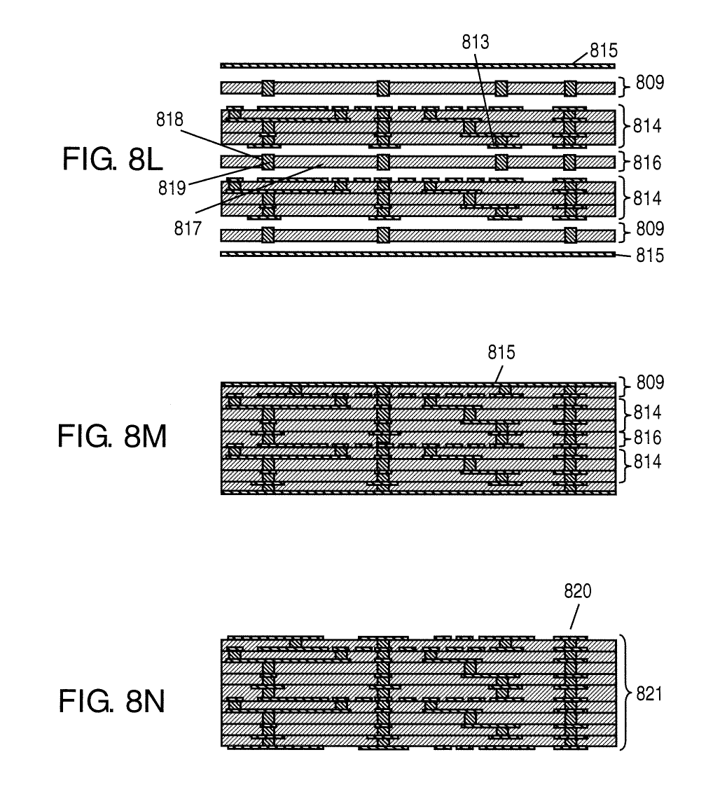

FIGS. 7A, 7B, and 8A-8K show a configuration and a manufacturing method of a multilayer wiring board according to a second exemplary embodiment of the present invention.

FIG. 7A shows ten-layered wiring board 701 as an example of the multilayer wiring board according to the present invention.

Ten-layered wiring board 701 shown in FIG. 7A has through-holes 702 filled with conductive paste 703, thereby establishing an electrical connection between wirings as in the first exemplary embodiment. Ten-layered wiring board 701 is characterized by having regions where conductive paste 707 filled in through-holes 706 is highly compressed from both sides by wirings 705 formed in, as inner layers, four-layered wiring boards 704 having high stiffness.

The connection region “A” of FIG. 7A is now described in detail with reference to FIG. 7B.

Wirings 705 disposed on both sides of conductive paste 707 are previously formed on the front and rear sides of adjacent four-layered wiring boards 704 having high stiffness in such a manner as to project from four-layered wiring boards 704. Wirings 705 are embedded in electrically insulating substrate 708 at both ends of conductive paste 707 in such a manner as to strongly compress conductive paste 707. Four-layered wiring boards 704 have a certain level of stiffness with no local variations, which can be caused by the uneven density of the wirings, thereby allowing conductive paste 707 to be compressed uniformly within the surface.

The four-layered wiring board has been described as an example of a multilayer wiring board with increased stiffness, but the layer structure is not limited to this. Alternatively, six or more layered double-sided wiring board can be used to provide the same effect of equalizing the compression. As a result, conductive paste 707 can provide a more stable electrical connection, and through-holes 706 can be made smaller in diameter.

Ten-layered wiring board 701 is formed through a three-time heat-and-pressure process and a three-time circuit-forming process. This allows wirings 709 that are formed in the outermost layers shown in FIG. 7B to have lower position variations, which are caused by variations in residual stress, thereby having higher positioning precision than in the conventional example.

A manufacturing method for the multilayer wiring board according to the second exemplary embodiment is now described with reference to FIGS. 8A to 8N.

FIG. 8A shows electrically insulating substrate 801.

In FIG. 8B, protective film 802 is laminated on both sides of electrically insulating substrate 801.

In FIG. 8C, through-holes 803 are formed, for example, by laser machining to penetrate electrically insulating substrate 801 and protective film 802.

In FIG. 8D, conductive paste 804 as a conductive material is filled into through-holes 803. In FIG. 8E, protective film 802 is removed. In FIG. 8F, wiring materials 805 in the form of foil are stacked on both sides of electrically insulating substrate 801.

In FIG. 8G, wiring materials 805 are bonded to electrically insulating substrate 801 through a heat-and-pressure process. The heat-and-pressure process thermally hardens conductive paste 804, thereby establishing an electrical connection between wiring materials 805 and conductive paste 804.

In FIG. 8H, wiring materials 805 are etched to form circuits, thereby achieving double-sided wiring board 807, which has wirings 806.

In FIG. 8I, wiring materials 808, electrically insulating connection substrates 809, and double-sided wiring board 807 are stacked each other. Electrically insulating connection substrates 809 are formed in a manner similar to the procedure shown in FIGS. 8A to 8E by forming through-holes 811 in electrically insulating substrates 810 and filling conductive paste 812 into through-holes 811.

In FIG. 8J, wiring materials 808 are bonded to the electrically insulating substrates through a heat-and-pressure process. At the same time, double-sided wiring board 807 is also bonded to the electrically insulating substrates. The heat-and-pressure process thermally hardens the conductive paste in the same manner as in FIG. 8G, bringing wiring materials 808 into close contact with double-sided wiring board 807 via the conductive paste, thereby establishing an electrical connection.

In FIG. 8K, the wiring materials on the outermost layers are etched to form circuits, thereby achieving four-layered wiring board 814, which has wirings 813.

In FIG. 8L, wiring materials 815, electrically insulating connection substrates 809, four-layered wiring boards 814, and electrically insulating connection substrate 816 are stacked each other.

Electrically insulating connection substrate 816 is formed in a manner similar to the procedure shown in FIGS. 8A to 8E by forming through-holes 818 in electrically insulating substrate 817 and filling conductive paste 819 into through-holes 818.

The position and dimension of wirings 813 of four-layered wiring boards 814 having small wiring variations are previously measured, and the measurement results are used to correct the position data of through-holes 818 of electrically insulating connection substrate 816. As a result, through-holes 818 can be highly aligned with wirings 813 in the same manner as in the first exemplary embodiment.

Wirings 813 projecting from four-layered wiring boards 814 are embedded in electrically insulating connection substrate 816 at both ends of conductive paste 819. As a result, conductive paste 819 can provide a more stable electrical connection, and through-holes 818 can be made smaller in diameter.

The materials of conductive paste 819 and electrically insulating substrate 817, which can be selected in the same manner as in the first exemplary embodiment, are not described here.

The four-layered wiring boards are characterized by including wiring layers as inner layers and by having higher stiffness and lower stiffness variations due to their larger thickness than the double-sided wiring boards. The positional variation of the wirings in the outermost layers is larger than in the double-sided wiring boards as the result of the two-time heat-and-pressure process and the two-time circuit-forming process, but is smaller than in the six or more layered wiring board shown in the conventional example.

In FIG. 8M, wiring materials 815, electrically insulating connection substrates 809, four-layered wiring boards 814, and electrically insulating connection substrate 816 are bonded to each other through the heat-and-pressure process. The heat-and-pressure process thermally hardens the conductive paste in the same manner as in FIG. 8G, bringing four-layered wiring boards 814 into close contact with each other, and also bringing four-layered wiring boards 814 into close contact with wiring materials 815 via the conductive paste, thereby establishing an electrical connection.

In FIG. 8N, wiring materials 815 on the outermost layers are etched to form circuits, thereby achieving ten-layered wiring board 821, which has wirings 820. Wirings 820 are formed through a three-time heat-and-pressure process and a three-time circuit-forming process. As a result, wirings 820 have lower position variations, which are caused by variations in residual stress, thereby having higher positioning precision than in the conventional example.

The second exemplary embodiment has described the ten-layered wiring board as an example of a multilayer wiring board; however, the number of layers of the wiring board is not limited to ten. The number of components to be alternately stacked in FIG. 8L can be changed, or the four-layered wiring boards can be replaced by a wiring board having other numbers of layers. It is preferable to change the number of layers according to a required level of stiffness, thereby improving the stability of compressing the conductive paste. It is also possible to select components that can prevent warpage of a finished multilayer wiring board. It is more preferable to select a combination of different wiring boards that warp in opposite directions so as not to be affected by warpage of the components having high stiffness.

The manufacturing method according to the present invention allows a wiring board to be manufactured through a three-time heat-and-pressure process and a three-time circuit-forming process regardless of the number of layers of the wiring board. This has an advantage of being highly productive in forming a multilayer wiring board having a large number of layers.

### Third Exemplary Embodiment

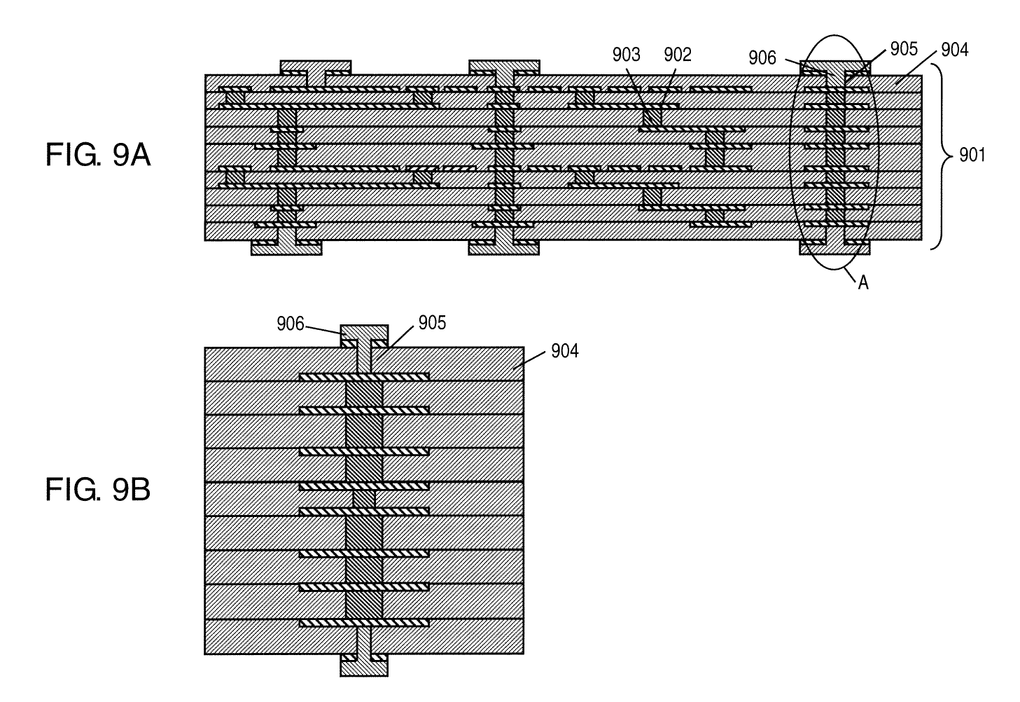

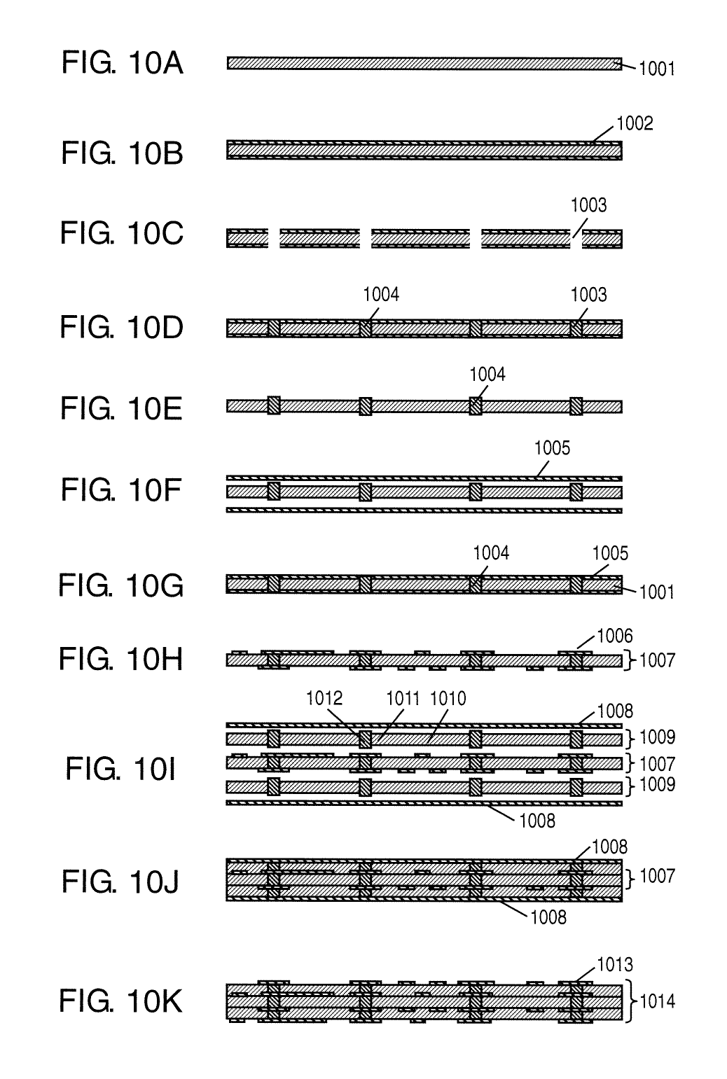

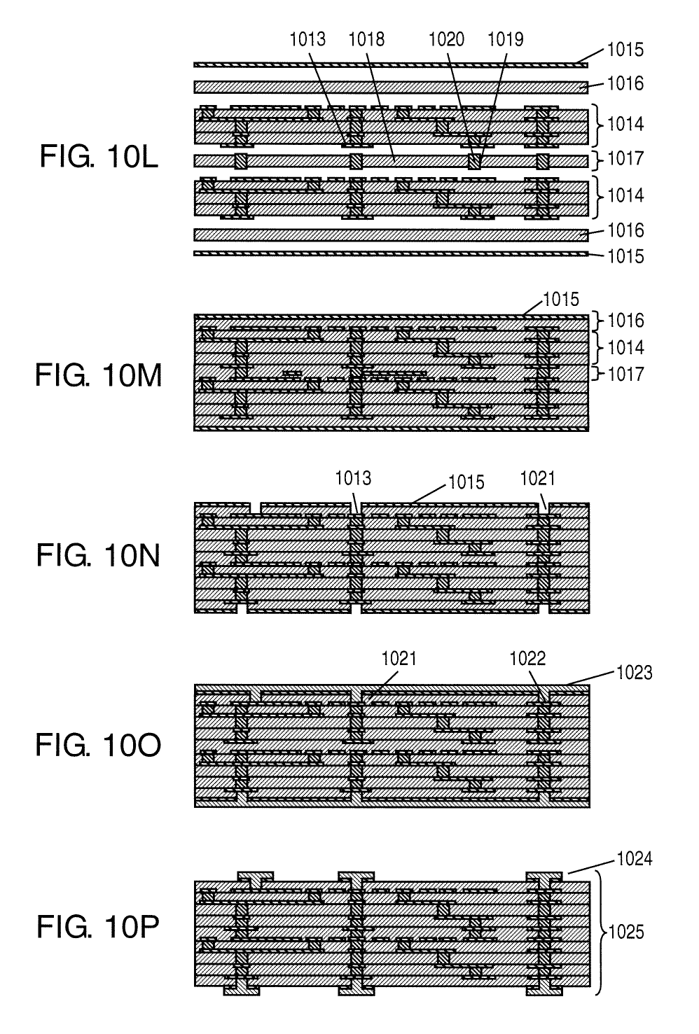

FIGS. 9A, 9B, 10A-10P show a configuration and a manufacturing method of a multilayer wiring board according to a third exemplary embodiment of the present invention.

The components that have been described in the former exemplary embodiments will be described in a simplified manner.

FIG. 9A shows ten-layered wiring board 901 as an example of the multilayer wiring board according to the present invention.

Ten-layered wiring board 901 shown in FIG. 9A has through-holes 902 filled with conductive paste 903, thereby establishing an electrical connection between wirings as in the same manner as in the first and second exemplary embodiments. Ten-layered wiring board 901 is characterized in that electrically insulating substrates 904 as the outermost layers have non-through-holes 905, which are filled with filled vias 906, thereby establishing an electrical connection.

The connection region “A” shown in FIG. 9A is now described in detail with reference to FIG. 9B.

This configuration increases the range of material choices for electrically insulating substrates 904 as the outmost layers, thereby providing more variety of substrates.

Non-through-holes 905 are plated to stabilize connection. This allows non-through-holes 905 to have small diameters, and the wirings in the outermost layers to be formed at high density.

In the case where electrically insulating substrates 904 are made of a thin material that does not include a core material such as glass cloth, electrical connection can be made by using non-through-holes 905 having a diameter not exceeding 30 microns.

In FIGS. 9A and 9B, filled vias 906 are formed by plating non-through-holes 905, however, conformal vias can be used instead. The inner layers of the multilayer wiring board have the configuration shown in the second exemplary embodiment, but may alternatively have the configuration shown in the first exemplary embodiment.

A manufacturing method for the multilayer wiring board according to the third exemplary embodiment is now described with reference to FIGS. 10A to 10P.

FIG. 10A shows electrically insulating substrate 1001.

In FIG. 10B, protective film 1002 is laminated on both sides of electrically insulating substrate 1001.

In FIG. 10C, through-holes 1003 are formed, for example, by laser machining to penetrate electrically insulating substrate 1001 and protective film 1002.

In FIG. 10D, conductive paste 1004 as a conductive material is filled into through-holes 1003. In FIG. 10E, protective film 1002 is removed.

In FIG. 10F, wiring materials 1005 in the form of foil are stacked on both sides of electrically insulating substrate 1001.

In FIG. 10G, wiring materials 1005 are bonded to electrically insulating substrate 1001 through a heat-and-pressure process. The heat-and-pressure process thermally hardens conductive paste 1004, thereby establishing an electrical connection between wiring materials 1005 and conductive paste 1004.

In FIG. 10H, wiring materials 1005 are etched to form circuits, thereby achieving double-sided wiring board 1007, which has wirings 1006.

In FIG. 10I, wiring materials 1008, electrically insulating connection substrates 1009, and double-sided wiring board 1007 are stacked each other. Electrically insulating connection substrates 1009 are formed in a manner similar to the procedure shown in FIGS. 10A to 10E by forming through-holes 1011 in electrically insulating substrates 1010 and filling conductive paste 1012.

In FIG. 10J, wiring materials 1008 are bonded to electrically insulating substrates 1010 through a heat-and-pressure process. At the same time, double-sided wiring board 1007 is also bonded to electrically insulating substrates 1010. The heat-and-pressure process thermally hardens conductive paste 1012 in the same manner as in FIG. 10G, bringing double-sided wiring board 1007 into close contact with wiring materials 1008 via conductive paste 1012, thereby establishing an electrical connection.

In FIG. 10K, wiring materials 1008 on the outermost layers are etched to form circuits, thereby achieving four-layered wiring board 1014, which has wirings 1013.

In FIG. 10L, wiring materials 1015, electrically insulating substrates 1016, four-layered wiring boards 1014, and electrically insulating connection substrate 1017 are stacked each other. Electrically insulating connection substrate 1017 is formed in a manner similar to the procedure shown in FIGS. 10A to 10E by forming through-holes 1019 in electrically insulating substrate 1018 and filling conductive paste 1020.

Wirings 1013 projecting from four-layered wiring boards 1014 are embedded in electrically insulating connection substrate 1017 at both ends of conductive paste 1020. As a result, conductive paste 1020 can provide a more reliable electrical connection, and through-holes 1019 can be made smaller in diameter.

The position and dimension of wirings 1013 can be previously measured, and through-holes 1019 can be processed based on the measurement results as in the first and second exemplary embodiments.

Electrically insulating substrates 1016 can be made of the same materials as those used in the first and second exemplary embodiments, but are more preferably made of different materials in order to improve the manufacturing process stability and to provide functionality.

For example, using thermosetting resin with high fluidity ensures the ease of embedding densely arranged wirings, and allows the wiring board to have a smooth surface regardless of the unevenness of density of the wirings on the inner layer pattern. Furthermore, electrically insulating substrates 1016 can be made of a highly heat-conductive material filled with an inorganic filler such as calcium hydroxide, silica, or magnesium oxide at high density. This provides high radiation performance when heat generating components are mounted at high density.

Thus, the multilayer wiring board of the present invention is suitable for a board mounted with semiconductor devices such as high-speed LSIs or LEDs at high density. Furthermore, using as electrically insulating substrates 1016 a material having high frequency characteristics and low ε or tan δ such as PPE, PPO, or Teflon (registered trademark) can provide high-speed/high-frequency transmission.

The use of a material having a high glass transition temperature provides a board capable of being mounted with bare chips at high temperatures. In this case, electrically insulating substrates 1016 are illustrated without a conductive paste because through-holes filled with the conductive paste are not disposed in the product area. However, forming through-holes filled with the conductive paste outside the product area can prevent electrically insulating substrates 1016 from skidding sideways in the heat-and-pressure process, so that a pressure that is closer to being uniform can be applied to electrically insulating connection substrate 1017.

In FIG. 10M, wiring materials 1015 are bonded to electrically insulating connection substrates 1016, four-layered wiring boards 1014, and electrically insulating connection substrate 1017 through the heat-and-pressure process.

The heat-and-pressure process compresses and thermally hardens the conductive paste in the same manner as in FIG. 10G, bringing four-layered wiring boards 1014 into close contact with each other via the conductive paste, thereby establishing an electrical connection.

In FIG. 10N, wiring materials 1015 are surface-treated to improve heat absorption, and then non-through-holes 1021 are formed by carbon dioxide laser or YAG laser.

Non-through-holes 1021 can be formed by carbon dioxide laser or YAG laser by previously etching the portions of wiring materials 1015 where non-through-holes 1021 are to be formed by pattern film photography, semiconductor laser, or other methods.

To improve productivity with the use of carbon dioxide laser, wirings 1022 that are directly underneath non-through-holes 1021 are preferably subjected to a surface treatment to selectively etch metal crystal planes so as to improve heat absorption. The surface treatment involves selectively etching the metal crystal planes only on one side of the four-layered wiring board.

After the surface treatment to selectively etch the metal crystal planes, it is preferable to dispose an anticorrosive film with a thickness of 300 angstroms or less on the wirings. This achieves both the connection performance of the conductive paste and high productivity with the use of carbon dioxide laser.

Wirings 1022 are preferably made thicker on the side of non-through-holes 1021 in order to prevent them from being dissolved by carbon dioxide laser.

A process for removing resin residue generated during the formation of non-through-holes 1021 is applied; then, electroless plating is applied to form a conductive film in the non-through-holes; and electroplating is applied to form conductive films 1023 as shown in FIG. 10O. In general, the resin residue is removed using a solution having oxidizing properties such as potassium permanganate or a plasma treatment. The electroless plating is performed using copper or nickel.

Electroplating is generally performed using copper or nickel.

Conductive films 1023, for example, can be applied along the walls of non-through-holes 1021 by conformal plating, or can be filled into non-through-holes 1021 by filled via plating.

Non-through-holes 1021 can have a diameter as small as about 30 microns while maintaining an electrical connection because wirings 1022 and conductive films 1023 are metal-bonded to each other.

It is preferable to use filled via plating in order to fill non-through-holes 1021 with conductive films 1023. This is because filled via plating allows the wirings on non-through-holes 1021 to be flat so as to prevent solder voids due to gas generated from substrates during the mounting of components, thereby improving connection reliability with the surface-mounted components in the same manner as in the first and second exemplary embodiments.

In FIG. 10P, the conductive film and the wiring material are etched at the same time to form circuits, thereby achieving ten-layered wiring board 1025, which has wirings 1024. Wirings 1024 can be mounted at a fine pitch by making their diameter as small as non-through-holes 1021.

In the manufacturing method described in the third exemplary embodiment, a plurality of four-layered wiring boards shown in the second exemplary embodiment are bonded to each other. It is, however, understood that the double-sided wiring boards described in the first exemplary embodiment can be used to provide similar effects.

The manufacturing method according to the present invention allows a wiring board to be manufactured through a three-time heat-and-pressure process and a three-time circuit-forming process regardless of the number of layers of the wiring board. This has an advantage of being highly productive in forming a multilayer wiring board having a large number of layers.

### INDUSTRIAL APPLICABILITY

As described above, the present invention can prevent dimensional variation in the procedure, which is caused by remaining residual stress, thereby improving the positional precision of the wirings in the outermost layers. As a result, a multilayer wiring board having high interlayer connection reliability can be manufactured with high productivity, and can be applied to a wide variety of multilayer wiring boards and their manufacturing method.

### REFERENCE MARKS IN THE DRAWINGS

102, 106, 203, 211, 405, 702, 706, 803, 811, 818, 902, 1003, 1011, 1019 through-hole
103, 107, 204, 212, 216, 404, 504, 703, 707, 804, 812, 819, 903, 1004, 1012, 1020 conductive paste
104, 207, 307-1, 307-2, 403, 807, 1007 double-sided wiring board (wiring board)
105, 206, 214, 406, 605, 705, 709, 806, 813, 820, 1006, 1013, 1022 wiring
108, 201, 309, 708, 801, 810, 817, 904, 1001, 1010, 1016, 1018 electrically insulating substrate
202, 802, 1002 protective film
205, 208, 301, 402, 501, 602, 805, 808, 815, 1005, 1008, 1015 wiring material
209, 210, 310-1, 310-2, 310-3, 401, 502, 601, 809, 816, 1009, 1017 electrically insulating connection substrate
213, 410, 505 laminated plate
407 heat tool
409 welded area
506 SUS plate
704, 714, 1014 four-layered wiring board (wiring board)
905, 1021 non-through-hole
1023 conductive film

1-18. (canceled)

19. A multilayer wiring board comprising:
wiring boards each having wirings on both sides thereof; and
electrically insulating substrates each having through-holes filled with a conductive paste, wherein
the wiring boards and the electrically insulating substrates are stacked alternately, and
of the wirings on both sides of the wiring boards sandwiching the electrically insulating substrates, the wirings in contact with the electrically insulating substrates are embedded in the electrically insulating substrates, and
a height of the through-holes is smaller than a thickness of the electrically insulating substrates.

20. The multilayer wiring board of claim 19, wherein
the wiring boards form a four-layered wiring board.

21. The multilayer wiring board of claim 19 comprising
a plurality of the wiring boards; and
a plurality of the electrically insulating substrates, wherein
the plurality of the wiring boards have different levels of stiffness from each other.

22. The multilayer wiring board of claim 19 comprising:
a plurality of the wiring boards; and
a plurality of the electrically insulating substrates, wherein
the plurality of the wiring boards are stacked in such a manner as to warp in opposite directions to each other.

23. A multilayer wiring board comprising:
an electrically insulating connection substrate having through-holes filled with a conductive paste;
a wiring board having wirings on both sides of the electrically insulating connection substrate;
an electrically insulating substrate stacked on the wiring board; and
wirings formed in outermost layers, wherein
a material of the electrically insulating substrate is different from a material of the electrically insulating connection substrate or of the wiring board.

24. The multilayer wiring board of claim 23, wherein
the material of the electrically insulating substrate and the material of the electrically insulating connection substrate or of the wiring board each contain a thermosetting resin that exhibits fluidity at a certain temperature or above; and
the fluidity of the resin contained in the electrically insulating substrate is higher than the fluidity of the resin contained in the electrically insulating connection substrate or in the wiring board.

25. The multilayer wiring board of claim 23, wherein
the electrically insulating substrate has non-through-holes including a conductive film; and
the wirings of the wiring board and the wirings formed in the outermost layers are electrically connected via the conductive film.

26. A manufacturing method for a multilayer wiring board, comprising:
preparing wiring boards each having wirings, the wiring boards being each formed of an electrically insulating substrate;
preparing electrically insulating connection substrates each having through-holes filled with a conductive paste;
preparing a laminated plate by alternately staking the wiring boards and the electrically insulating connection substrates and by stacking wirings in outermost layers;
heating and pressing the laminated plate; and
forming circuits by etching wiring materials in outermost layers of the laminated plate, wherein
the wirings of the wiring boards disposed at both ends of the conductive paste in the electrically insulating connection substrate are subjected to heat and pressure while being embedded in the electrically insulating connection substrate.

27. The manufacturing method for the multilayer wiring board of claim 26, wherein
the step of preparing the wiring boards each having the wirings includes:
laminating a protective film on both sides of the electrically insulating substrates;
forming through-holes in the electrically insulating substrates and in the protective film;
filling a conductive paste into the through-holes;
removing the protective film;
stacking wiring materials on both sides of each of the electrically insulating substrates;
heating and pressing the wiring materials; and
etching the wiring materials to form circuits for obtaining a double-sided wiring board having wirings.

28. The manufacturing method for the multilayer wiring board of claim 26, wherein
the step of preparing the wiring boards each having the wirings is a step of preparing a four or more layered wiring board having a certain level of stiffness.

29. The manufacturing method for the multilayer wiring board of claim 27, wherein
the step of etching the wiring material to form circuits, thereby obtaining the double-sided wiring board having the wirings includes a step of removing residual stress of the double-sided wiring board.

30. The manufacturing method for the multilayer wiring board of claim 26, wherein
each of the electrically insulating substrates forming the wiring boards, and each of the electrically insulating connection substrates contains at least resin; and
the electrically insulating connection substrates have a higher resin content than the electrically insulating substrates.

31. The manufacturing method for the multilayer wiring board of claim 26, wherein
each of the electrically insulating substrates forming the wiring boards, and each of the electrically insulating connection substrates contain resin that exhibits fluidity at a certain temperature or above; and
the fluidity of the resin contained in the electrically insulating connection substrates is higher than the fluidity of the resin contained in the electrically insulating substrates.

32. The manufacturing method for the multilayer wiring board of claim 26, wherein
the step of preparing the laminated plate by alternately staking the wiring boards and the electrically insulating connection substrates and by stacking the wiring materials in the outermost layers includes a step of temporarily fixing a part of the electrically insulating connection substrates to the double-sided wiring board by welding;
the temporary fixing involves applying heat and pressure to a welded area provided in the laminated plate by using a heat tool.

33. The manufacturing method for a multilayer wiring board of claim 32, wherein
the welded area includes at least:
through-holes in the electrically insulating connection substrates, the through-holes being filled with a conductive paste; and
through-holes in the double-sided wiring board, the through-holes being filled with the conductive paste.

34. The manufacturing method for a multilayer wiring board of claim 32, wherein
in the welded areas provided in the laminated plate, the wiring materials in the outermost layers have been selectively removed.

35. The manufacturing method for the multilayer wiring board of claim 26, wherein
the step of heating and pressing the laminated plate includes a step of heating and pressing a plurality of the laminated plates stacked via SUS plates; and
the laminated plates are stacked in such a manner as to be alternated up and down, rotated 180 degrees horizontally, or displaced from each other.
